(19) United States
(12) Patent Application Publication
(10) Pub. No.: US 2024/0411201 A1
(43) Pub. Date: Dec. 12, 2024

(54) OPTICAL PATH CONTROL MEMBER AND DISPLAY DEVICE COMPRISING SAME

(71) Applicant: LG INNOTEK CO., LTD., Seoul (KR)

(72) Inventors: In Hae LEE, Seoul (KR); Mun Yeong SON, Seoul (KR)

(21) Appl. No.: 18/699,119

(22) PCT Filed: Sep. 30, 2022
(86) PCT No.: PCT/KR2022/014759

§ 371 Date: Apr. 5, 2024

(30) Foreign Application Priority Data
Oct. 5, 2021 (KR) 10-2021-0131982

(51) Int. Cl. G02F 1/29

(52) U.S. Cl. CPC G02F 1/29

(57) ABSTRACT

An optical path control member, according to one embodiment, comprises: a first substrate; a first electrode arranged on the first substrate; a second substrate arranged on the first substrate; a second electrode arranged under the second substrate; a light conversion unit arranged between the first electrode and the second electrode; and a buffer layer arranged between the first electrode and the light conversion unit, wherein the buffer layer has a thickness of 0.1 μm or less.

### TECHNICAL FIELD

An embodiment relates to an optical path control member, and to a display device including the same.

### BACKGROUND ART

A light blocking film blocks transmitting of light from a light source, and is attached to a front surface of a display panel which is a display device used for a mobile phone, a notebook, a tablet PC, a vehicle navigation device, a vehicle touch, etc., so that the light blocking film adjusts a viewing angle of light according to an incident angle of light to express a clear image quality at a viewing angle needed by a user when the display transmits a screen.

In addition, the light blocking film may be used for the window of a vehicle, building or the like to shield outside light partially to prevent glare, or to prevent the inside from being visible from the outside.

That is, the light blocking film may be an optical path control member that controls the movement path of light to block light in a specific direction and transmit light in a specific direction. Accordingly, it is possible to control the viewing angle of the user by controlling a transmission angle of the light by the light blocking film.

Meanwhile, such a light blocking film may be divided into a light blocking film that can always control the viewing angle regardless of the surrounding environment or the user's environment and a switchable light blocking film that allow the user to turn on/off the viewing angle control according to the surrounding environment or the user's environment.

Such a switchable light blocking film may be implemented by converting an accommodating portion of a light conversion unit into a light transmitting part and a light blocking part by filling the inside of the accommodating portion with particles that may move when a voltage is applied and a light conversion material including a dispersion liquid for dispersing the particles and by dispersing and aggregating the particles.

Meanwhile, the light conversion material of the light conversion unit may move by a voltage applied to the switchable light blocking film.

In this case, there is a problem that a driving speed of the switchable light blocking film is reduced because the voltage is not effectively transferred from the electrode to the light conversion unit due to a resistance of an adhesive layer disposed between the light conversion unit and the electrode.

Therefore, there is a need for an optical path control member having a new structure capable of solving the above problems.

### DISCLOSURE

### Technical Problem

An embodiment relates to an optical path control member having improved reliability and driving speed.

### Technical Solution

An optical path control member according to an embodiment comprises: a first substrate; a first electrode disposed on the first substrate; a second substrate disposed on the first substrate, a second electrode disposed under the second substrate; a light conversion unit disposed between the first electrode and the second electrode; and a buffer layer disposed between the first electrode and the light conversion unit, wherein a thickness of the buffer layer is 0.1 μm or less.

### Advantageous Effects

An optical path control member according to the embodiment includes a buffer layer having a thickness within a set range. Accordingly, a surface resistance of the buffer layer can be reduced. Accordingly, the buffer layer disposed between the accommodating portion and the first electrode can prevent a decrease in a moving speed of a voltage applied in a direction of the accommodating portion. Accordingly, the driving speed of the optical path control member can be improved.

In addition, since the buffer layer has the thickness within the set range, it is possible to sufficiently maintain adhesion of the buffer layer. Accordingly, it is possible to prevent a base portion of a light conversion unit and the first electrode from being delaminated or lifted in some regions. Therefore, reliability of the optical path control member can be improved.

### DESCRIPTION OF DRAWINGS

FIG. 1 is a perspective view of an optical path control member according to an embodiment.

FIGS. 2 and 3 are cross-sectional views taken along line A-A′ in FIG. 1.

FIG. 4 is an enlarged view of region B in FIG. 2.

FIG. 5 is a graph for comparing driving speeds of optical path control members according to Example and Comparative Examples.

FIGS. 6 and 7 are cross-sectional views of a display device to which an optical path control member according to an embodiment is applied.

FIGS. 8 to 10 are views for describing one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to drawings. The optical path control member described below may be a switchable light blocking film that is driven in a public mode and a light blocking mode according to application of a voltage.

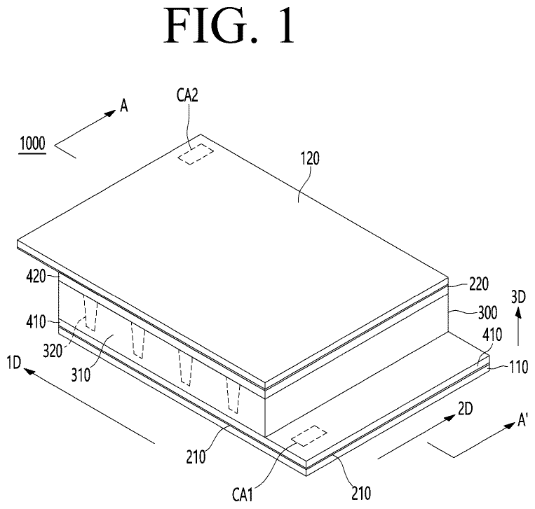

FIG. 1 is a perspective view of an optical path control member according to an embodiment.

Referring to FIG. 1, an optical path control member 1000 according to the embodiment may include a first substrate 110, a second substrate 120, a first electrode 210, a second electrode 220, and a light conversion unit 300.

The first substrate 110 and the second substrate 120 may be rigid or flexible.

In addition, the first substrate 110 and the second substrate 120 may be transparent. For example, the first substrate 110 and the second substrate 120 may include a transparent substrate capable of transmitting light.

The first substrate 110 and the second substrate 120 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example, but the embodiment is not limited thereto.

In addition, the first substrate 110 and the second substrate 120 may be a flexible substrate having flexible characteristics.

Further, the first substrate 110 and the second substrate 120 may be a curved or bended substrate. That is, the optical path control member including the first substrate 110 and the second substrate 120 may also be formed to have flexible, curved, or bent characteristics. Accordingly, the optical path control member according to the embodiment may be changed to various designs.

The first substrate 110 and the second substrate 120 may have a thickness within a set range. For example, a thickness T1-1 of the first substrate 100 and a thickness T1-2 of the second substrate 120 may be 30 μm to 100 μm. In detail, the thickness T1-1 of the first substrate 110 and the thickness T1-2 of the second substrate 120 may be 40 μm to 80 μm. In more detail, the thickness T1-1 of the first substrate 110 and the thickness T1-2 of the second substrate 120 may be 50 μm to 60 μm.

When the thickness T1-1 of the first substrate 110 and the thickness T1-2 of the second substrate 120 exceed 100 μm, the thickness T1-1 of the first substrate 110 and the thickness T1-2 of the second substrate 120 increase. Accordingly, the overall thickness and weight of the optical path control member may be increased.

In addition, when the thickness T1-1 of the first substrate 110 and the thickness T1-2 of the second substrate 120 are less than 30 μm, the thickness T1-1 of the first substrate 110 and the thickness T1-2 of the second substrate 120 decrease. Accordingly, the first substrate 110 and the second substrate 120 may not sufficiently support the electrodes on the substrate.

The thickness T1-1 of the first substrate 110 and the thickness T1-2 of the second substrate 120 may be the same or similar within the set range.

The first electrode 210 and the second electrode 220 may include a transparent conductive material. For example, the first electrode 210 and the second electrode 220 may include a conductive material having a light transmittance of about 80% or more. For example, the first electrode 210 and the second electrode 220 may include a metal oxide such as indium tin oxide, indium zinc oxide, copper oxide, tin oxide, zinc oxide, titanium oxide, etc.

Alternatively, the first electrode 210 and the second electrode 220 may include various metals to realize low resistance. For example, the first electrode 210 and the second electrode 220 may include at least one metal of chromium (Cr), nickel (Ni), copper (Cu), aluminum (Al), silver (Ag), molybdenum (Mo), Gold (Au), titanium (Ti), and alloys thereof.

The first electrode 210 and the second electrode 220 may have a thickness within a set range. For example, the thickness T2-1 of the first electrode 210 and the thickness T2-2 of the second electrode 220 may have a thickness of 0.2 μm to 1 μm. In detail, the thickness T2-1 of the first electrode 210 and the thickness T2-2 of the second electrode 220 may have a thickness of 0.2 μm to 0.5 μm.

When the thickness T2-1 of the first electrode 210 and the thickness T2-2 of the second electrode 220 are greater than 1 μm, the thickness T2-1 of the first electrode 210 and the thickness T2-2 of the second electrode 220 increase. Accordingly, the overall thickness and weight of the optical path control member may be increased.

In addition, when the thickness T2-1 of the first electrode 210 and the thickness T2-2 of the second electrode 220 are less than 0.2 μm, the thickness T2-1 of the first electrode 210 and the thickness T2-2 of the second electrode 220 decrease. Accordingly, driving characteristics of the optical path control member may be deteriorated due to an increase in electrode resistance of the optical path control member.

The thickness T2-1 of the first electrode 210 and the thickness T2-2 of the second electrode 220 may be the same or similar within the set range.

Connection electrodes may be disposed on each of the first substrate 110 and the second substrate 120. In detail, a first connection electrode CA1 formed by exposing the first electrode 210 may be disposed on the first substrate 110. In addition, a second connection electrode CA2 formed by exposing the second electrode 220 may be disposed on the second substrate 120.

The optical path control member may be electrically connected to an external printed circuit board or a flexible printed circuit board through the first connection electrode CA1 and the second connection region CA2.

For example, a pad portion is disposed on the first connection electrode CA1 and the second connection electrode CA2. Subsequently, a conductive adhesive including at least one of an anisotropic conductive film (ACF) and an anisotropic conductive paste (ACP) is disposed between the pad portion and the printed circuit board or the flexible printed circuit board. Accordingly, the pad portion and the printed circuit board or the flexible printed circuit board may be connected to each other.

Alternatively, the conductive adhesive including at least one of an anisotropic conductive film (ACF) and an anisotropic conductive paste (ACP) may be disposed between the first connection electrode CA1 and the second connection electrode CA2 and the printed circuit board or the flexible printed circuit board. Accordingly, the pad portion and the printed circuit board or the flexible printed circuit board may be directly connected without the pad portion.

The light conversion unit 300 may be disposed between the first substrate 110 and the second substrate 120. In detail, the light conversion unit 300 may be disposed between the first electrode 210 and the second electrode 220.

A buffer layer 410 may be disposed between the light conversion unit 300 and the first electrode 210. The buffer layer 410 may improve adhesion between the first electrode 220 and the light conversion unit 300 including different materials. That is, the buffer layer 410 may be a primer layer disposed between the light conversion unit 300 and the first electrode 210.

An adhesive layer 420 may be disposed between the light conversion unit 300 and the second electrode 220. The light conversion unit and the second electrode 220 may be adhered through the adhesive layer 420.

The buffer layer 410 and the adhesive layer 420 may include a transparent material capable of transmitting light. As an example, the buffer layer 410 may include a transparent resin, and the adhesive layer 420 may include an optically clear adhesive (OCA).

The optical path control member may extend in a first direction 1D, a second direction 2D, and a third direction 3D.

In detail, the optical path control member may include a first direction 1D corresponding to a length or width direction of the optical path control member, a second direction 2D extending in a direction different from the first direction 1D and corresponding to the length or width direction of the optical path control member, and a third direction 3D extending in a direction different from the first direction 1D and the second direction 2D and corresponding to a thickness direction of the optical path control member.

For example, the first direction 1D may be defined as the length direction of the optical path control member, the second direction 2D may be defined as the width direction perpendicular to the first direction 1D, and the third direction 3D may be defined as the thickness direction of the optical path control member. Alternatively, the first direction 1D may be defined as the width direction of the optical path control member, the second direction 2D may be defined as the length direction of the optical path control member perpendicular to the first direction 1D, and the third direction 3D may be defined as the thickness direction of the optical path control member.

Hereinafter, for convenience of description, the first direction 1D will be described as the length direction of the optical path control member, the second direction 2D will be described as the width direction of the optical path control member, and the third direction 3D will be described as the thickness direction of the optical path control member.

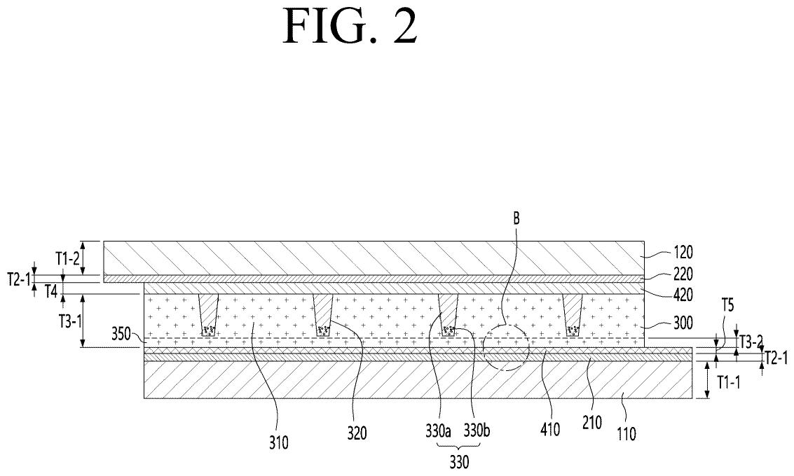

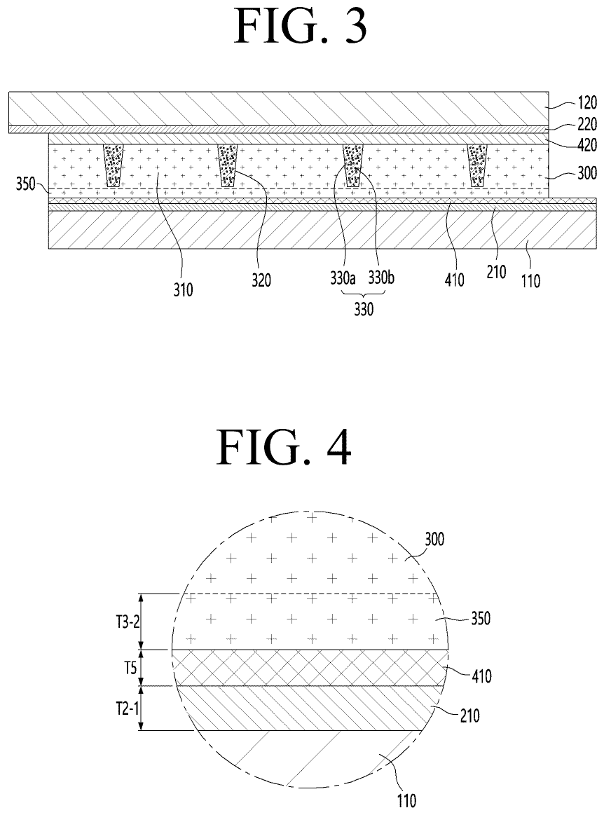

FIGS. 2 and 3 are cross-sectional views taken along line A-A′ in FIG. 1, and FIG. 4 is an enlarged view of region B in FIG. 2.

Referring to FIGS. 2 to 4, the light conversion unit 300 may include a plurality of partition wall portions 310, a plurality of accommodating portions 320, and a base portion 350.

The light conversion unit 300 may include the plurality of partition wall portions 310 and the plurality of accommodating portions 320. In addition, the partition wall portion 310 and the accommodating portion 320 may be alternately disposed with each other. That is, one accommodating portion 320 may be disposed between two adjacent partition wall portions 310. In addition, one partition wall portion 310 may be disposed between two adjacent accommodating portions 320.

The base portion 350 may be disposed under the accommodating portion 320. In detail, the base portion 350 may be disposed between the accommodating portion 320 and the buffer layer 410. In more detail, the base portion 350 may be disposed between a lower surface of the accommodating portion 320 and an upper surface of the buffer layer 510. Accordingly, the light conversion unit 300 may be adhered to the first electrode 210 through the base portion 350 and the buffer layer 410.

In addition, an adhesive layer 420 may be disposed between the partition wall portion 310 and the second electrode 220. Accordingly, the light conversion unit 300 and the second electrode 220 may be adhered.

The base portion 350 may be a region formed by releasing a resin material constituting the partition wall portion 310 and the accommodating portion 320 from a mold member to form the partition wall portion 310 and the accommodating portion 320. The base portion may include the same material as the partition wall portion 310. That is, the base portion 350 and the partition wall portion 310 may be integrally formed.

The base portion 350 may have a thickness within a set range. For example, a thickness T3-2 of the base portion 350 may be 10% or less with respect to a thickness T3-1 of the light conversion unit. In detail, the thickness T3-2 of the base portion 350 may be 5% to 10% with respect to the thickness T3-1 of the light conversion unit. In detail, the thickness T3-2 of the base portion 350 may be 6% to 9% with respect to the thickness T3-1 of the light conversion unit.

When the thickness T3-2 of the base portion 350 exceeds 10% with respect to the thickness T3-1 of the light conversion unit, a distance between the accommodating portion 320 and the first electrode 210 may increase. Accordingly, a voltage transmitted to the inside of the accommodating portion may decrease, and accordingly, driving characteristics of the optical path control member may be deteriorated.

The partition wall portion 310 may transmit light. In addition, light transmittance of the accommodating portion 320 may be changed according to the application of a voltage.

In detail, a light conversion material 330 may be disposed in the accommodating portion 320. The light transmittance of the accommodating portion 320 may be changed by the light conversion material 330. The light conversion material 330 may include light conversion particles 330b that move according to the application of the voltage and a dispersion liquid 330a for dispersing the light conversion particles 330b. In addition, the light conversion material 330 may further include a dispersant for preventing aggregation of the light conversion particles 330b.

The light conversion particles 330b inside the dispersion liquid 330a may move according to the application of the voltage. For example, referring to FIG. 2, surfaces of the light conversion particles 330b inside the dispersion liquid 330a are charged with a negative (−) charge. When a positive voltage is applied through the first electrode 210 and the second electrode 220, the light conversion particles 330b move toward the first electrode 210 or the second electrode 220. Accordingly, the accommodating portion 320 may become a light transmitting part.

In addition, referring to FIG. 3, when a negative voltage is applied through the first electrode 210 and the second electrode 220, the light conversion particles 330b are dispersed again into the dispersion liquid 330a. Accordingly, the accommodating portion 320 may become a light blocking part.

Meanwhile, the buffer layer 410 and the adhesive layer 420 described above may have a thickness within a set range. The buffer layer 410 and the adhesive layer 420 may be formed to have different thicknesses. In detail, a thickness of the adhesive layer 420 may be greater than that of the buffer layer 410.

For example, a thickness T4 of the adhesive layer 420 may be 30 μm or less. In detail, the thickness T4 of the adhesive layer 420 may be 10 μm to 30 μm. In more detail, the thickness T4 of the adhesive layer 420 may be 15 μm to 25 μm.

When the thickness T4 of the adhesive layer 420 exceeds 30 μm, the thickness of the adhesive layer 420 increases. Accordingly, an overall thickness of the optical path control member may increase. In addition, when the thickness T4 of the adhesive layer 420 is less than 10 μm, the adhesion of the adhesive layer 420 may be reduced. Accordingly, the light conversion unit 300 and the second electrode 220 may be delaminated. Accordingly, reliability of the optical path control member may be deteriorated.

A thickness T5 of the buffer layer 410 may be 0.1 μm or less. In detail, the thickness T5 of the buffer layer T5 may be 0.02 μm to 0.1 μm.

When the thickness T5 of the buffer layer 410 exceeds 0.1 μm, when a voltage moves toward the accommodating portion 320 from the first electrode 210, the magnitude of resistance of the buffer layer 410 disposed between the first electrode 210 and the accommodating portion 320 may increase. Accordingly, the moving speed of the light conversion particle 330b inside the accommodating portion 320 may decrease. Accordingly, a speed of switching from a public mode to a privacy mode or a speed of switching from the privacy mode to the public mode may decrease. Accordingly, since a user may visually recognize screen switching of the optical path control member, user's visibility may be reduced.

In addition, when the thickness T5 of the buffer layer 410 is less than 0.02 μm, the buffer layer 410 does not have sufficient adhesion. Accordingly, the buffer layer 410 may be delaminated from the first electrode 210 or the base portion 350. Accordingly, since the adhesion between the first electrode 210 and the light conversion unit 300 is reduced, the reliability of the optical path control member may be deteriorated.

The buffer layer 410 may have a different thickness from other layers. In detail, the thickness T5 of the buffer layer 410 may be different from the thickness T1-1 of the first substrate, the thickness T1-2 of the second substrate, the thickness T2-1 of the first electrode, the thickness of the second electrode T2-2, the thickness of the base portion T3-2, and the thickness of the adhesive layer T4. In more detail, the thickness T5 of the buffer layer 410 may be smaller than the thickness T1-1 of the first substrate, the thickness T1-2 of the second substrate, the thickness T2-1 of the first electrode, the thickness of the second electrode T2-2, the thickness of the base portion T3-2, and the thickness of the adhesive layer T4.

For example, the thickness T2-1 of the first electrode and the thickness T2-2 of the second electrode may be between the thickness T5 of the buffer layer and the thickness T3-2 of the base portion. For example, a thickness of at least one of the first electrode and the second electrode may be greater than the thickness T5 of the buffer layer and smaller than the thickness T3-2 of the base portion.

That is, the optical path control member according to an embodiment may prevent a decrease in driving speed of the path control member by minimizing the thickness of the buffer layer 410 for adhering the first electrode 410 and the light conversion unit 300.

Hereinafter, the present invention will be described in more detail through the driving speed according to the thickness of the buffer layer of the optical path control member according to Examples and Comparative Examples. These examples are merely illustrative in order to describe the present invention in more detail. Therefore, the present invention is not limited to these examples.

### EXAMPLE

A first electrode was disposed on a first substrate, and a second electrode was disposed on a second substrate. Subsequently, a buffer layer was disposed on the first electrode, an accommodating portion was formed on the buffer layer, and a light conversion unit filled with a light conversion material was disposed in the accommodating portion.

Subsequently, an optical path control member was manufactured by disposing an adhesive layer on the light conversion unit and adhering the second substrate on which the second electrode was disposed through the adhesive layer.

The buffer layer included Triethoxy3-(oxiranylmethoxy) propylsilane.

In this case, the thickness of the buffer layer was 0.02 μm to 0.1 μm.

Subsequently, adhesive properties of the first electrode and the light conversion unit were checked, and a time taken for switching from a light blocking mode to a public mode was measured by applying power to the optical path control member.

The time taken for switching from the light blocking mode to the public mode is defined as a time taken for the light transmittance of the optical path control member from about 0% to about 70% or more.

In addition, adhesive properties of the buffer layer and a surface resistance of the buffer layer were measured.

### Comparative Example 1

After manufacturing the optical path control member in the same manner as in Example, except that the thickness of the buffer layer was adjusted to be greater than 0.1 μm and less than 0.5 μm, adhesive properties of the first electrode and the light conversion unit were checked, and the time taken for switching from the light blocking mode to the public mode was measured by applying power to the optical path control member.

The time taken for switching from the light blocking mode to the public mode is defined as a time taken for the light transmittance of the optical path control member from about 0% to about 70% or more based on an average thickness of the buffer layer (more than 0.1 μm to less than 0.5 μm).

In addition, the adhesive properties of the buffer layer and the surface resistance of the buffer layer were measured.

### Comparative Example 2

After manufacturing the optical path control member in the same manner as in Example, except that the thickness of the buffer layer was adjusted to 0.5 μm to 2 μm, the adhesive characteristics of the first electrode and the light conversion unit were checked, and the time taken for switching from the light blocking mode to the public mode was measured by applying power to the optical path control member.

Here, the time taken for switching from the light blocking mode to the public mode is defined as a time taken for the light transmittance of the optical path control member from about 0% to about 70% or more based on an average thickness of the buffer layer (0.5 μm to less than 2 μm).

In addition, the adhesive properties of the buffer layer and the surface resistance of the buffer layer were measured.

TABLE 1

| | | Comparative | Comparative |
|---|---|---|---|
| | Example | Example 1 | Example 2 |
| Adhesive properties | OK | NG | NG |
| Surface resistance | 120~180 | 10⁸~10⁹ | 10¹⁰~10¹² |
| (Ω/□) | | | |

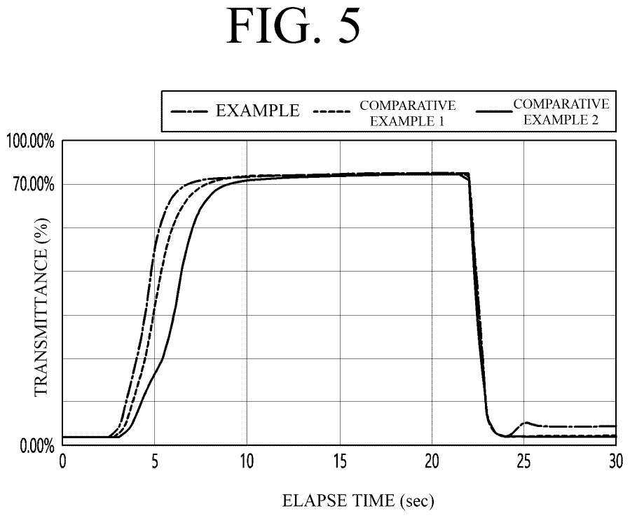

Referring to FIG. 5, the time taken for switching from the light blocking mode to the public mode in the optical path control member according to Example and Comparative Example 1 is smaller than that of the optical path control member according to Comparative Example 2.

In detail, the time taken for switching from the light blocking mode to the public mode in the optical path control member according to Example is 3 seconds or less. On the other hand, the time taken for switching from the light blocking mode to the public mode in the optical path control member according to Comparative Example 1 and Comparative Example 2 is more than 3 seconds.

That is, the buffer layer of the optical path control member according to Example has a low surface resistance in the range of 120Ω/□ to 180Ω/□. Accordingly, the driving speed of the optical path control member may be improved.

Therefore, the time taken for switching from the light blocking mode to the public mode in the optical path control member according to Example is a short time. Accordingly, when a user applies and uses the optical path control member to a display device, it is difficult to recognize a screen change according to a change in transmittance. Therefore, the user's visibility may be improved.

On the other hand, the time taken for switching from the light blocking mode to the public mode in the optical path control member according to Comparative Example 1 and Comparative Example 2 is a long time. Accordingly, when the user applies and uses the optical path control member to the display device, it is possible to recognize a screen change according to a change in transmittance. Accordingly, the user's visibility may be reduced.

In addition, referring to Table 1, in the optical path control member according to Example, the light conversion unit and the first electrode have sufficient adhesive properties. Accordingly, the optical path control member according to Example may prevent the light conversion unit and the first electrode from being lifted during use. Accordingly, the optical path control member according to Example may have improved reliability and driving characteristics.

On the other hand, the optical path control members according to Comparative Examples 1 and 2 have low adhesive properties between the light conversion unit and the first electrode. Accordingly, in the optical path control members according to Comparative Examples 1 and 2, the light conversion unit and the first electrode may be lifted during use. Therefore, reliability and driving characteristics of the optical path control member may be deteriorated.

That is, in the optical path control member according to Example, the surface resistance of the buffer layer may be reduced by the buffer layer having a thickness within a set range. Accordingly, it is possible to prevent a moving speed of a voltage applied toward the accommodating portion from being reduced by the buffer layer. Therefore, the driving speed of the optical path control member may be improved. In addition, since the buffer layer has sufficient adhesion, it is possible to prevent the base portion and the first electrode from being delaminated or lifted in some regions. Accordingly, the optical path control member may have improved reliability.

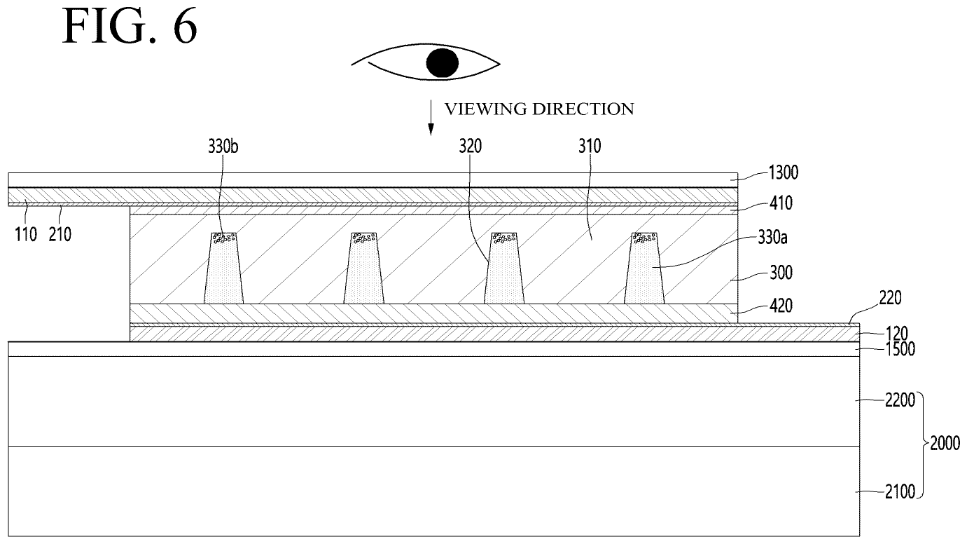

Hereinafter, referring to FIGS. 6 to 10 a display device to which an optical path control member according to an embodiment is applied will be described.

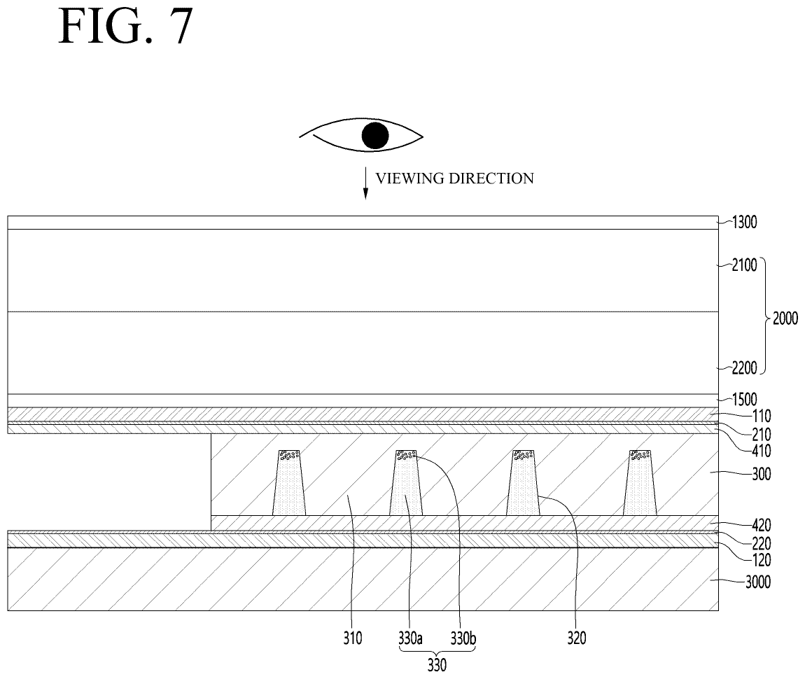

Referring to FIGS. 6 to 7, An optical path control member 1000 according to an embodiment may be disposed on or under a display panel 2000.

The display panel 2000 and the optical path control member 1000 may be disposed to be adhered to each other. For example, the display panel 2000 and the optical path control member 1000 may be adhered to each other via an adhesive layer 1500. The adhesive layer 1500 may be transparent. For example, the adhesive layer 1500 may include an adhesive or an adhesive layer including an optical transparent adhesive material.

The adhesive layer 1500 may include a release film. In detail, when adhering the optical path control member and the display panel, the optical path control member and the display panel may be adhered after the release film is removed.

The display panel 2000 may include a first base substrate 2100 and a second base substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first base substrate 2100 including a thin film transistor (TFT) and a pixel electrode and the second base substrate 2200 including color filter layers are adhered to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is adhered to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 7, the optical path control member may be disposed under the liquid crystal panel and on the backlight unit 3000, and the optical path control member may be disposed between the backlight unit 3000 and the display panel 2000.

Alternatively, as shown in FIG. 6, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

That is, light emitted from the display panel 2000 or the backlight unit 3000 may move from the second substrate 120 of the optical path control member toward the first substrate 110.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. Specifically, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

In addition, it is shown in the drawings that the light conversion unit of the optical path control member according to the embodiment is in a direction parallel or perpendicular to an outer surface of the second substrate, but the light conversion unit is formed to be inclined at a predetermined angle from the outer surface of the second substrate. Through this, a moire phenomenon occurring between the display panel and the optical path control member may be reduced.

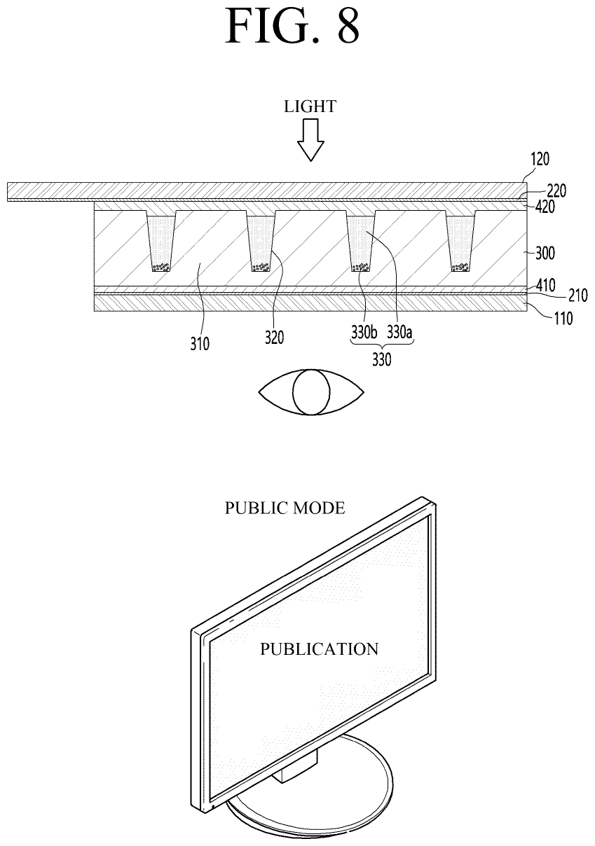

Referring to FIGS. 8 to 10, an optical path control member according to an embodiment may be applied to various display devices.

Referring to FIGS. 8 to 10, the optical path control member according to the embodiment may be applied to a display device that displays a display.

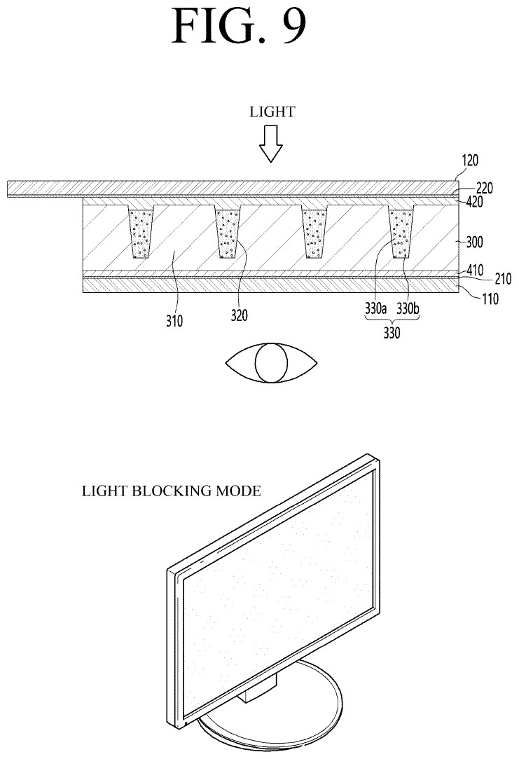

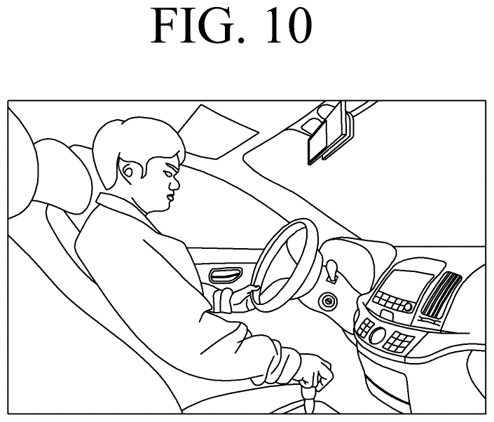

For example, when power is applied to the optical path control member as shown in FIG. 8, the accommodating portion functions as the light transmitting part, so that the display device may be driven in the public mode, and when power is not applied to the optical path control member as shown in FIG. 9, the accommodating portion functions as the light blocking part, so that the display device may be driven in the light blocking mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

In addition, referring to FIG. 10, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a first electrode disposed on the first substrate;
a buffer layer disposed on the first electrode;
a light conversion unit disposed on the buffer layer;
a second electrode disposed on the light conversion unit; and
a second substrate disposed on the second electrode,
wherein a thickness of the buffer layer is 0.1 μm or less.

2. The optical path control member of claim 1, wherein the thickness of the buffer layer is 0.02 μm to 0.1 μm.

3. The optical path control member of claim 1, wherein a surface resistance of the buffer layer is 120Ω/□ to 180Ω/□.

4. The optical path control member of claim 1, wherein the light conversion unit comprises a plurality of accommodating portions spaced apart from each other in a first direction;
a plurality of partition wall portions disposed between the plurality of accommodating portions to partition the plurality of accommodating portions; and
a base portion disposed between the plurality of accommodating portions and the buffer layer, wherein the thickness of the buffer layer is smaller than that of the base portion.

5. The optical path control member of claim 4, wherein the thickness of the base portion is 10% or less of that of the light conversion unit.

6. The optical path control member of claim 4, wherein a thickness of at least one of the first electrode and the second electrode is greater than that of the buffer layer and smaller than that of the base portion.

7. The optical path control member of claim 1, comprising an adhesive layer disposed between the light conversion unit and the second electrode,
wherein the thickness of the buffer layer is smaller than that of the adhesive layer.

8. A display device comprising:
a panel including at least one of a display panel and a touch panel; and
an optical path control member that is disposed on or under the panel,
wherein the optical path control member comprises:
a first substrate;
a first electrode disposed on the first substrate;
a buffer layer disposed on the first electrode;
a light conversion unit disposed on the buffer layer;
a second electrode disposed on the light conversion unit; and
a second substrate disposed on the second electrode, and
wherein a thickness of the buffer layer is 0.1 μm or less.

9. The display device of claim 8, wherein the panel comprises a liquid crystal display panel and a backlight unit disposed on the liquid crystal display panel,
wherein the optical path control member is disposed between the backlight unit and the liquid crystal display panel, and
wherein light emitted from the backlight unit moves from the second substrate toward the first substrate.

10. The display device of claim 8, wherein the panel comprises an organic light emitting diode panel,
wherein the optical path control member is disposed on the organic light emitting diode panel, and
wherein light emitted from the panel moves from the second substrate toward the first substrate.

11. The display device of claim 8, wherein the thickness of the buffer layer is 0.02 μm to 0.1 μm.

12. The display device of claim 8, wherein the light conversion unit includes a plurality of accommodating portions spaced apart from each other in a first direction;
a plurality of partition wall portions disposed between the plurality of accommodating portions to partition the plurality of accommodating portions; and
a base portion disposed between the plurality of accommodating portions and the buffer layer,
wherein the thickness of the buffer layer is smaller than that of the base portion.

13. The display device of claim 12, wherein a thickness of at least one of the first electrode and the second electrode is greater than that of the buffer layer and smaller than that of the base portion.

14. The display device of claim 8, comprising an adhesive layer disposed between the light conversion unit and the second electrode,
wherein the thickness of the buffer layer is smaller than that of the adhesive layer.
